(19) United States
(12) Patent Application Publication
(10) Pub. No.: US 2025/0224326 A1
(43) Pub. Date: Jul. 10, 2025

(54) SPECTROSCOPIC ELLIPSOMETER AND SUBSTRATE ANALYSIS METHOD USING THE SAME

(71) Applicant: SAMSUNG ELECTRONICS CO., LTD., Suwon-si (KR)

(72) Inventors: Jaeho KIM, Suwon-si (KR); Souk KIM, Suwon-si (KR); Younghoon SOHN, Suwon-si (KR)

(73) Assignee: SAMSUNG ELECTRONICS CO., LTD., Suwon-si (KR)

(21) Appl. No.: 18/774,473

(22) Filed: Jul. 16, 2024

(30) Foreign Application Priority Data
Jan. 9, 2024 (KR) 10-2024-0003824

(51) Int. Cl. G01N 21/21; G01N 21/95

(52) U.S. Cl. CPC G01N 21/211; G01N 21/9501; G01N 2021/213; G01N 2201/0634; G01N 2201/0635

(57) ABSTRACT

A spectroscopic ellipsometer includes a light source configured to emit light, a polarizer configured to polarize the light emitted from the light source, a substrate support supporting a substrate, a polarization analysis assembly that is rotatable and optically connected to the substrate support, and a spectroscope configured to disperse the light from the polarization analysis assembly, where the spectroscope includes a lens configured to change a propagation path of the light from the polarization analysis assembly, a line slit assembly including a slit extending linearly and configured to extract a portion of the light from the lens, a spectral dispersion device configured to disperse the light from the line slit assembly, and a plane detector optically connected to the spectral dispersion device and configured to continuously detect the dispersed light that is dispersed by the spectral dispersion device.

### CROSS-REFERENCE TO RELATED APPLICATION

This application is based on and claims priority under 35 U.S.C § 119 to Korean Patent Application No. 10-2024-0003824, filed on Jan. 9, 2024, in the Korean Intellectual Property Office, the disclosure of which is incorporated by reference herein in its entirety.

### BACKGROUND

Example embodiments of the disclosure relate to a spectroscopic ellipsometer and a substrate analysis method using the same.

A semiconductor device may be fabricated through various processes. After performing various semiconductor fabrication processes, a metrology and inspection may be executed to perform process evaluation and feedback. An increase in integration of a semiconductor may cause an increase in the number of test processes. The test process may be performed to detect semiconductor failures in advance.

Information disclosed in this Background section has already been known to or derived by the inventors before or during the process of achieving the embodiments of the present application, or is technical information acquired in the process of achieving the embodiments. Therefore, it may contain information that does not form the prior art that is already known to the public.

### SUMMARY

One or more example embodiments provide a spectroscopic ellipsometer that includes a line slit assembly providing a straight line-shaped slit in a spectroscope and a substrate analysis method using the same.

One or more example embodiments provide a spectroscopic ellipsometer that may be capable of obtaining spectral data of a substrate line region and a substrate analysis method using the same.

One or more example embodiments provide a spectroscopic ellipsometer that may be capable of determining Fourier coefficients and structural parameters of a substrate line region and a substrate analysis method using the same.

One or more example embodiments provide a spectroscopic ellipsometer that may allow a rotary spectroscope to obtain continuous polarization signals of a substrate line region and a substrate analysis method using the same.

One or more example embodiments provide a spectroscopic ellipsometer that may be capable of easily performing large-area analysis of a substrate and a substrate analysis method using the same.

Additional aspects will be set forth in part in the description which follows and, in part, will be apparent from the description, or may be learned by practice of the presented embodiments.

According to an aspect of an example embodiment, a spectroscopic ellipsometer may include a light source configured to emit light, a polarizer configured to polarize the light emitted from the light source, a substrate support supporting a substrate, a polarization analysis assembly that is rotatable and optically connected to the substrate support, and a spectroscope configured to disperse the light from the polarization analysis assembly, where the spectroscope includes a lens configured to change a propagation path of the light from the polarization analysis assembly, a line slit assembly including a slit extending linearly and configured to extract a portion of the light from the lens, a spectral dispersion device configured to disperse the light from the line slit assembly, and a plane detector optically connected to the spectral dispersion device and configured to continuously detect the dispersed light that is dispersed by the spectral dispersion device.

According to an aspect of an example embodiment, a spectroscopic ellipsometer may include a light source configured to emit light, a polarizer configured to polarize the light emitted from the light source, a substrate support configured to support a substrate, a rotatable analyzer configured to determine a degree of polarization of the light from the polarizer and a position of a polarization plane, and a spectroscope configured to disperse the light from the rotatable analyzer, wherein the spectroscope includes a first collimating lens configured to concentrate the light from the rotatable analyzer to form an image, a second collimating lens that is spaced apart from the first collimating lens and configured to parallel propagate the light from the first collimating lens, a line slit assembly between the first collimating lens and the second collimating lens and including a slit extending linearly, a spectral dispersion device optically connected to the second collimating lens and configured to disperse the light from the second collimating lens, and a plane detector optically connected to the spectral dispersion device and configured to continuously detect the dispersed light from the spectral dispersion device.

According to an aspect of an example embodiment, a substrate analysis method may include providing a substrate on a spectroscopic ellipsometer, and analyzing the substrate, where the spectroscopic ellipsometer may include a light source configured to emit light, a polarizer configured to polarize the light emitted from the light source, a substrate support configured to support the substrate, a rotatable polarization analysis assembly configured to determine information about polarization of the light from the substrate support, and a spectroscope configured to disperse the light from the rotatable polarization analysis assembly, where the spectroscope includes a line slit assembly including a slit extending linearly, a spectral dispersion device configured to disperse the light from the line slit assembly, and a plane detector optically connected to the spectral dispersion device, where the rotatable polarization analysis assembly includes an analyzer configured to determine the information about the polarization of the light from the substrate support, where the slit includes a first slit region and a second slit region, where the substrate includes a first substrate region corresponding to the first slit region, and a second substrate region corresponding to the second slit region, and where the analyzing the substrate includes rotating the rotatable polarization analysis assembly, measuring a continuous variation in intensity in accordance with a wavelength of the light caused by rotation of the rotatable polarization analysis assembly, measuring a first Fourier coefficient of the first slit region and a second Fourier coefficient of the second slit region, and obtaining structural parameters of the first substrate region and the second substrate region based on the first Fourier coefficient and the first Fourier coefficient.

### BRIEF DESCRIPTION OF DRAWINGS

The above and other aspects, features, and advantages of certain example embodiments of the present disclosure will be more apparent from the following description taken in conjunction with the accompanying drawings, in which:

FIG. 1 is a diagram illustrating a spectroscopic ellipsometer according to one or more embodiments;

FIG. 2 is a diagram illustrating a spectroscope according to one or more embodiments;

FIG. 3 is a diagram illustrating a spectroscopic ellipsometer according to one or more embodiments;

FIG. 4 is a diagram illustrating intensity in accordance with wavelength for each slit region of a slit according to one or more embodiments;

FIG. 5 is a diagram illustrating obtaining a Fourier coefficient for each slit region of a slit according to one or more embodiments;

FIG. 6 is a graph illustrating obtaining a structural parameter of a substrate according to one or more embodiments;

FIG. 7 is a diagram illustrating a spectroscope according to one or more embodiments;

FIG. 8 is a plan view illustrating a plane detector according to one or more embodiments;

FIG. 9 is a plan view illustrating a plane detector according to one or more embodiments;

FIG. 10 is a diagram illustrating a spectroscope according to one or more embodiments;

FIG. 11 is a plan view illustrating a plane detector according to one or more embodiments;

FIG. 12 is a plan view illustrating a plane detector according to one or more embodiments; and

FIG. 13 is a flowchart illustrating a substrate analysis method according to one or more embodiments.

### DETAILED DESCRIPTION

Hereinafter, example embodiments of the disclosure will be described in detail with reference to the accompanying drawings. The same reference numerals are used for the same components in the drawings, and redundant descriptions thereof will be omitted. The embodiments described herein are example embodiments, and thus, the disclosure is not limited thereto and may be realized in various other forms.

As used herein, expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

In this description, D1 may indicate a first direction, D2 may indicate a second direction that intersects the first direction D1, and D3 may indicate a third direction that intersects each of the first direction D1 and the second direction D2. The first direction DI may be referred to as an upward direction, and a direction opposite to the first direction DI may be referred to as a downward direction. In addition, each of the second direction D2 and the third direction D3 may be referred to as a horizontal direction.

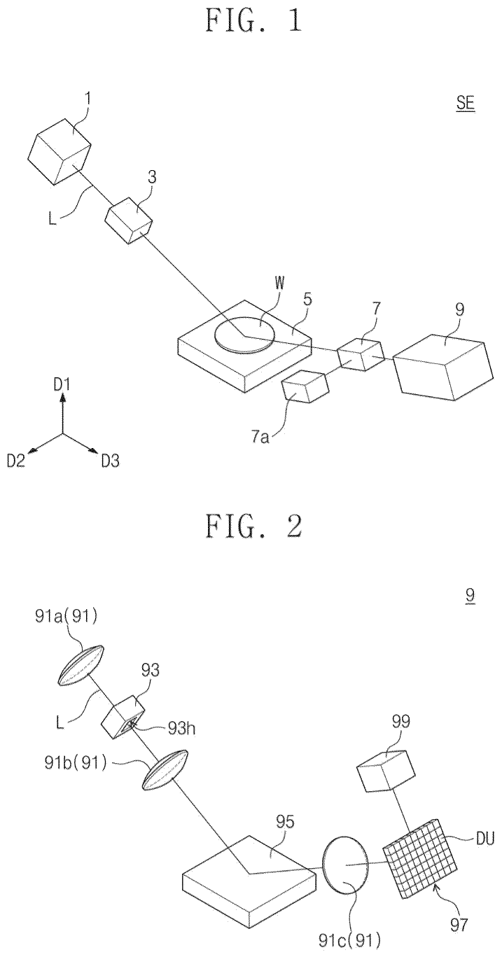

FIG. 1 is a diagram illustrating a spectroscopic ellipsometer according to one or more embodiments.

Referring to FIG. 1, a spectroscopic ellipsometer SE may include a light source 1, a polarizer 3, a substrate support 5, a polarization analysis assembly 7, a spectroscope 9, and a polarization rotator 7a.

The light source 1 may emit light L. A light L emitted from the light source 1 may be a white light. The light source 1 may emit the light L that oscillates in all directions. The light source 1 may emit the light L toward the polarizer 3. The light source 1 may generate the light L having a wavelength range from far-infrared to near-infrared.

The polarizer 3 may be optically connected to the light source 1. The polarizer 3 may be positioned between the light source 1 and the substrate support 5. The polarizer 3 may polarize the light L generated from the light source 1. The light L emitted from the polarizer 3 may be a polarized light. The polarizer 3 may cause extraction of the light L that oscillates in a predetermined direction. The light L emitted from the light source 1 may include various vibration waves having the same wavelength and different phases. The polarizer 3 may absorb the light L that oscillates in a specific direction. The polarizer 3 may only allow penetration of a vibration wave that is polarized in a direction perpendicular to the absorbed light L. The polarizer 3 may convert the light L generated from the light source 1 into a linearly polarized light. The light L that passes through the polarizer 3 may include a p-wave and an s-wave. The p-wave may be a wave with a propagation direction that is the same as the oscillation direction. The s-wave may be a wave with a propagation direction that is perpendicular to the oscillation direction.

The substrate support 5 may support a substrate W. The substrate W may include a silicon (Si) wafer. Embodiments are not limited thereto. The substrate support 5 may be optically connected to the polarizer 3. The substrate support 5 may be irradiated with the polarized light L from the polarizer 3. When the polarized light L is emitted to the substrate W, the polarization state of the light L that is reflected in accordance with optical properties of the substrate W or a structure of the substrate W. The reflection or refraction of the polarized light L may depend on a thin film, a refractive index, a thickness, or other optical or structural properties of the substrate W.

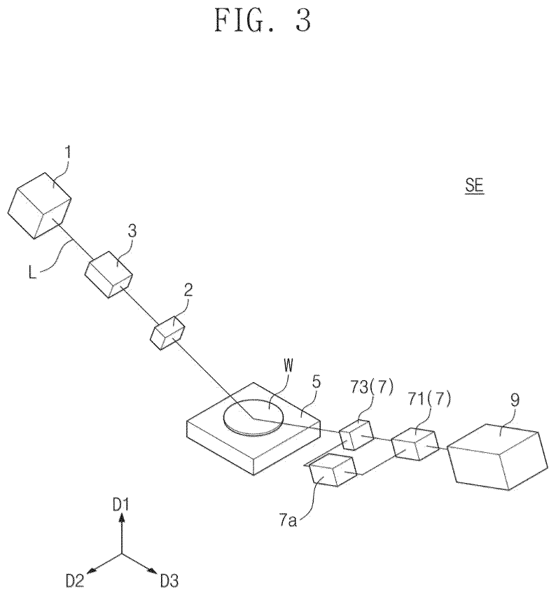

The polarization analysis assembly 7 may be optically connected to the substrate support 5. The light L received by the polarization analysis assembly 7 may be a polarized light. The light L that enters the polarization analysis assembly 7 may be different from the light L that enters the substrate support 5. The polarization analysis assembly 7 may include an analyzer (see 71 of FIG. 3). The analyzer 71 may determine the degree of polarization of the light L or a direction of a polarization plane. The analyzer 71 may have a structure substantially the same as that of the polarizer 3. The analyzer 71 may allow penetration of the light L that is polarized in a specific direction. For example, the analyzer 71 may allow penetration of the light L that is polarized in the first direction D1. However, the analyzer 71 may allow partial penetration of the light L that is polarized in a direction perpendicular to the first direction D1. The analyzer 71 may not allow penetration of the light L that is polarized in the second direction D2 perpendicular to the first direction D1. Information about a polarization state of the light L may be obtained due to the polarization direction of the light L that passes through the analyzer 71.

The polarization rotator 7a may be connected to the polarization analysis assembly 7. The polarization rotator 7a may be connected to the analyzer 71 or a second compensator (see 73 of FIG. 3). The polarization rotator 7a may rotate the polarization analysis assembly 7. The polarization rotator 7a may rotate the analyzer 71 or the second compensator 73. The polarization rotator 7a may change information about the light L that is reflected or refracted from the substrate support 5. As the polarization rotator 7a rotates the analyzer 71 or the second compensator 73, there may be a variation in intensity for each wavelength of the light L that reaches a plane detector (see 97 of FIG. 2).

The spectroscope 9 may be optically connected to the polarization analysis assembly 7. The spectroscope 9 may receive the light L released from the polarization analysis assembly 7. The spectroscope 9 may disperse the light L released from the polarization analysis assembly 7. The spectroscope 9 will be further described in detail below.

FIG. 2 is a diagram illustrating a spectroscope according to one or more embodiments.

Referring to FIG. 2, the spectroscope 9 may include a lens 91, a line slit assembly 93, a spectral dispersion device 95, a plane detector 97, and a central processing unit (CPU) 99.

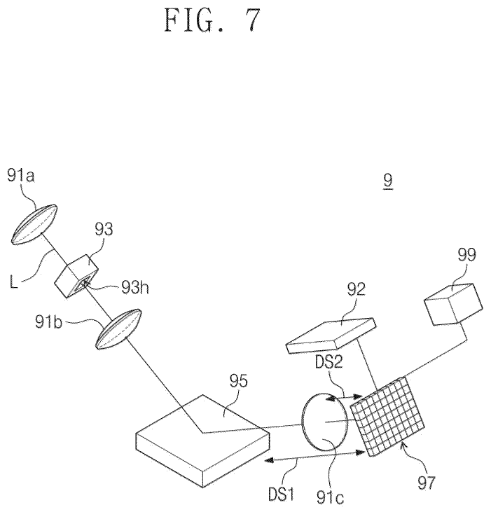

The lens 91 may include a first collimating lens 91a, a second collimating lens 91b, and a third lens 91c. The first collimating lens 91a and the second collimating lens 91b may maintain or control a propagation direction of the light L. The first collimating lens 91a may focus the light L, which is reflected from the substrate support 5, on a single point to form an image. The first collimating lens 91a may focus the light L, which is emitted parallelly, on an image spot. The second collimating lens 91b may be optically connected to the first collimating lens 91a. The second collimating lens 91b may change a traveling direction of the light L so as to achieve a parallel propagation of the light L that has passed through the image spot. The first collimating lens 91a and the second collimating lens 91b may continuously maintain the parallel propagation of the light L that parallel travels toward the spectroscope 9. The third lens 91c may be positioned between the plane detector 97 and the spectral dispersion device 95. The third lens 91c may cause the plane detector 97 to receive the light L. A second distance (see DS2 of FIG. 7) between the plane detector 97 and the third lens 91c may be adjusted by a plane driver (see 92 of FIG. 7). The plane driver 92 will be further described in detail below. An observation range and resolution of the light L may depend on the second distance DS2 between the plane detector 97 and the third lens 91c.

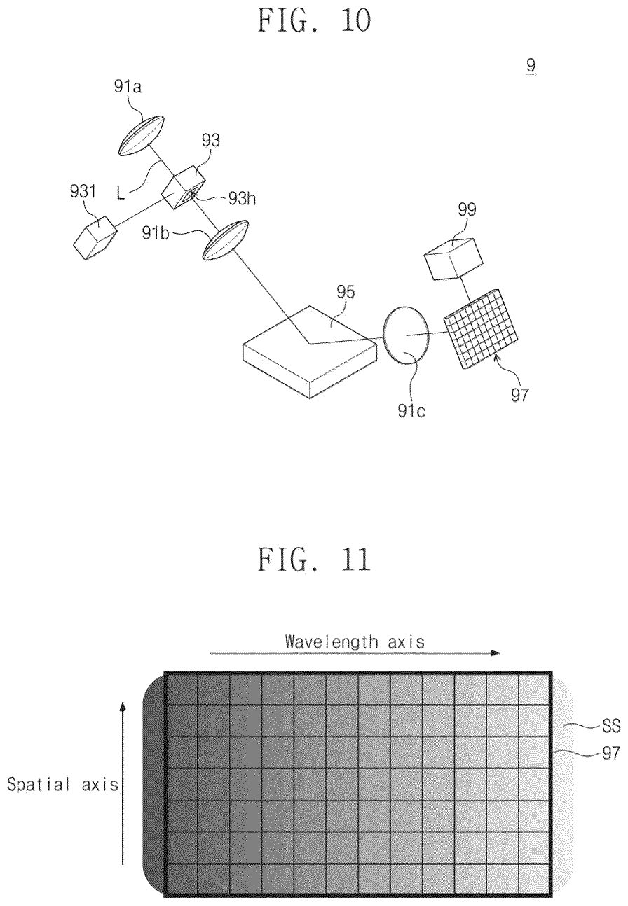

The line slit assembly 93 may be positioned between the first collimating lens 91a and the second collimating lens 91b. The line slit assembly 93 may be positioned at the image spot. The line slit assembly 93 may extract a portion of an image formed on the image spot. The line slit assembly 93 may extract a portion of the light L reflected from the substrate W. The line slit assembly 93 may extract a portion of the light L released from the lens 91. The line slit assembly 93 may include a slit 93h that extends linearly. The line slit assembly 93 may allow selective observation of the light L released from the slit 93h. The line slit assembly 93 may include a slit controller (see 931 of FIG. 10). The slit controller 931 will be further described below.

The spectral dispersion device 95 may disperse the light L. The spectral dispersion device 95 may be optically connected to the second collimating lens 91b. The spectral dispersion device 95 may include a prism or a diffraction grating. The prism may include a Nomarski prism, a Wallaston prism, or Rochon prism. However, the type of prism is not limited thereto. The diffraction grating may include a plurality of thin plates that are spaced apart from each other at a regular interval. When the light L enters the diffraction grating, the light L may be diffracted at an angle for each wavelength and then dispersed.

The plane detector 97 may be optically connected to the spectral dispersion device 95. The plane detector 97 may be optically connected to the third lens 91c. The plane detector 97 may continuously detect the dispersed light L. The plane detector 97 may have a wide plate shape. The plane detector 97 may include a plurality of detectors DU. The detectors DU may include a charge-coupled device (CCD) camera or a complementary metal-oxide-semiconductor (CMOS) image sensor. The plane detector 97 may be shaped like a rectangular hexahedron composed of a plurality of detectors both horizontally and vertically.

The CPU 99 may be connected to the plane detector 97. The CPU 99 may be electrically connected to the plane detector 97. Based on information about the light L detected by the plane detector 97, the CPU 99 may recognize a structure of the substrate W. The CPU 99 may perform a calculation for recognizing a structure of the substrate W. The following will describe how to recognize a structure of the substrate W.

FIG. 3 is a diagram illustrating a spectroscopic ellipsometer according to one or more embodiments.

Referring to FIG. 3, the spectroscopic ellipsometer SE may further include a first compensator 2 and a second compensator 73. For example, the spectroscopic ellipsometer SE may include the first compensator 2 positioned between the polarizer 3 and the substrate support 5. The first compensator 2 may delay a phase of the light L. The polarization analysis assembly 7 may include the second compensator 73 positioned between the substrate support 5 and the analyzer 71. The second compensator 73 may change a phase of the light L. Although FIG. 3 depicts both of the first compensator 2 and the second compensator 73, the first compensator 2 and the second compensator 73 may be selectively included in the spectroscopic ellipsometer SE (i.e., one or both of the first compensator 2 and the second compensator 73 may be omitted in some embodiments). The spectroscopic ellipsometer SE may include one of the first compensator 2 and the second compensator 73.

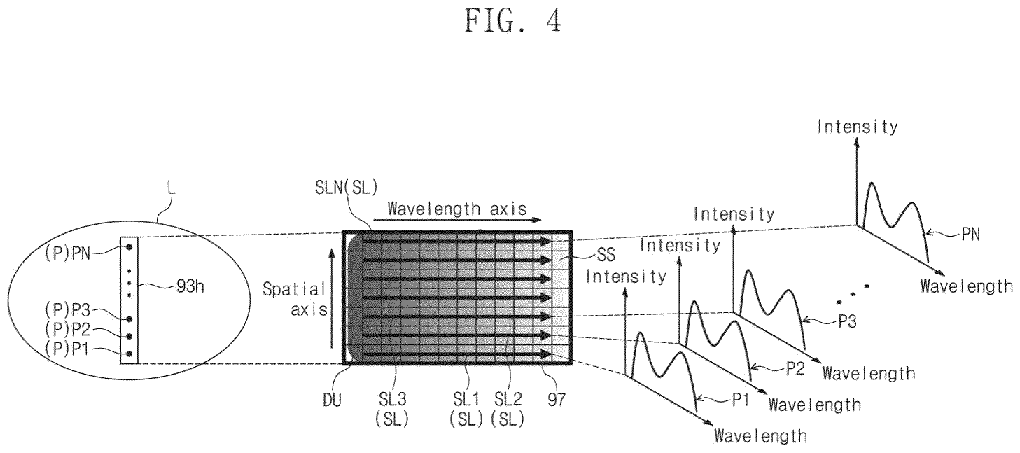

FIG. 4 is a diagram illustrating intensity in accordance with wavelength for each slit region of a slit according to one or more embodiments.

Referring to FIG. 4, there may be provided the plane detector 97 in which a spectrum is formed for each slit region P. The slit 93h may include a plurality of slit regions P. For example, the slit 93h may include a first slit region P1, a second slit region P2, and a third slit region P3. The first slit region P1 may indicate the slit region P positioned at a lowermost portion of the slit 93h. The second slit region P2 may be positioned on the first slit region P1 in the slit 93h. An N^{th} slit region PN may be positioned on an (N-1)^{st} slit region. The number of the slit regions P may depend on a length of the slit 93h. Each slit region P may correspond to a predetermined region of the substrate W. For example, the light L released from the first slit region PI may include information about a first substrate region. The first substrate region corresponding to the first slit region P1 may be changed when the line slit assembly 93 or the substrate support 5 moves. Similarly, the second slit region P2 may correspond to a second substrate region. The third slit region P3 may correspond to a third substrate region. The light L concentrated on the image spot may be larger than the slit 93h. The slit 93h may allow only a portion of the light L to pass therethrough. The light L released from the slit 93h may form a spectrum zone SS on the plane detector 97.

A front face of the plane detector 97 may have a rectangular shape composed of a plurality of detectors DU both horizontally and vertically. A horizontal side of the front face of the plane detector 97 may be a wavelength axis. A vertical side of the front face of the plane detector 97 may be a spatial axis. The light L released from each slit region P may horizontally form a spectrum on the plane detector 97. For example, the light L released from the first slit region P1 may horizontally form a first spectral line SL1 on a lowermost portion of the spectrum zone SS. The light L released from the second slit region P2 may horizontally form a second spectral line SL2 on the first spectral line SL1. Different slit regions P may form different spectral lines SL. The spectral line SL may have intensity different depending on wavelength.

FIG. 4 depicts graphs showing intensity in accordance with wavelength for each spectral line SL. A horizontal axis of the graph may indicate wavelength. A vertical axis of the graph may indicate intensity. Each slit region P may obtain a graph showing intensity in accordance with wavelength of the light L. The CPU 99 may obtain data corresponding to intensity in accordance with wavelength of the light L, and may generate a graph showing the intensity in accordance with wavelength of the light L as many as the number of the spectral lines SL.

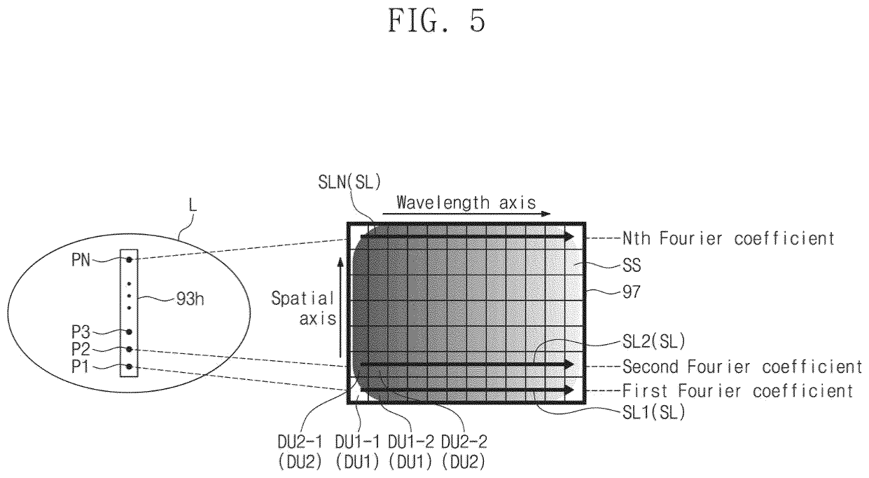

FIG. 5 is a diagram illustrating obtaining a Fourier coefficient for each slit region of a slit according to one or more embodiments.

Referring to FIG. 5, there may be provided the plane detector 97 capable of obtaining a Fourier coefficient for each slit region P. As the polarization rotator 7a rotates the polarization analysis assembly 7, the light L incident on the spectroscope 9 may be changed. The light L incident on the spectroscope 9 may be continuously changed due to the rotation of the polarization rotator 7a. Therefore, the light L that passes through the slit 93h may also be continuously changed. The plane detector 97 may include a plurality of detectors DU that detect the spectrum zone SS. A first detector DUI may refer to the detector DU that detects the first spectral line SL1. A 1-1^{st} detector DU1-1 may refer to the detector DU positioned at a leftmost position among the first detectors DU1. A 1-2^{nd} detector DU1-2 may refer to the detector DU adjacent to the 1-1^{st} detector DU1-1 among the first detectors DU1. A 1-Nth detector may refer to the detector DU positioned at a rightmost position among the first detectors DU1. The more right position of the detector DU, the longer wavelength of detected light L. The light L detected by the 1-2^{nd} detector DU1-2 may have a wavelength longer than that of the light L detected by the 1-1^{st} detector DU1-1. Similarly, a second detector DU2 may refer to the detector DU that detects the second spectral line SL2. A 2-1^{st} detector DU2-1 may refer to the detector DU positioned at a leftmost position among the second detectors DU2. A 2-2^{nd} detector DU2-2 may refer to the detector DU adjacent to the 2-1^{st} detector DU2-1 among the second detectors DU2. The light L detected by the 2-1^{st} detector DU2-1 may have a wavelength shorter than that of the light L detected by the 2-2^{nd} detector DU2-2. The light L detected by the detector DU may have intensity that is changed depending on a rotation angle of the polarization analysis assembly 7. Based on continuous data obtained by the detector DU, the CPU 99 may obtain a Fourier coefficient for each slit region P. The CPU 99 may use the Fourier coefficient to determine an elliptical polarization coefficient for each slit region P. The elliptical polarization coefficient may include Ψ, an amplitude variation ratio of a p-wave and an s-wave when the light L is reflected from the substrate W, and A, a phase difference ratio of a p-wave and an s-wave when the light L is reflected from the substrate W. The CPU 99 may use the elliptical polarization coefficient to determine a structural parameter for each slit region P. The structural parameter may represent information about a recess, a critical dimension (CD), or a thickness of a layer formed on the substrate W. The CD may indicate a width of a pattern formed on the substrate W. A constant size of the CD may induce the formation of exact fine patterns. A reduction in size of the CD may cause the formation of fine patterns. The recess may indicate a pattern that is formed recessed from top toward bottom surfaces of the substrate W. For example, based on continuous data of the first spectral line SL1, the CPU 99 may obtain a first Fourier coefficient. The CPU 99 may use the first Fourier coefficient to determine a first elliptical polarization coefficient of the first slit region P1. The CPU 99 may use the first elliptical polarization coefficient to determine a first structural parameter of the first substrate region. Likewise, the CPU 99 may determine a second structural parameter of the second substrate region.

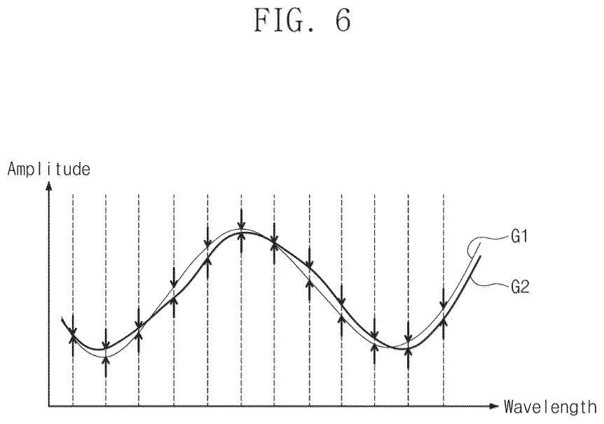

FIG. 6 is a graph illustrating obtaining a structural parameter of a substrate according to one or more embodiments.

Referring to FIG. 6, a first graph G1 of an actual structural parameter of the substrate W is illustrated and a second graph G2 of a determined structural parameter of the substrate W is illustrated. A horizontal axis of each of the first graph G1 and the second graph G2 may indicate wavelength. A vertical axis of each of the first graph G1 and the second graph G2 may indicate amplitude. The first graph G1 and the second graph G2 may be plotted by using the light L released from the first slit region P1. The first graph G1 and the second graph G2 may include information about a structural parameter of the first substrate region. The first graph G1 may include information about a first actual structural parameter of the first substrate region. The second graph G2 may include information about a first determine structural parameter of the first substrate region. The first graph G1 may be a reference graph that is not changed. When the first structural parameter is changed, the second graph G2 may be changed to be similar to the first graph G1. The first actual structural parameter may refer to a first structural parameter that is obtained when the second graph G2 is changed to coincide with the first graph G1. Information about a structure of the first substrate region may be acquired by obtaining the first structural parameter that is maximally similar to the first actual structural parameter. Similarly, it may be possible to acquire structural information about the second substrate region and the third substrate region.

FIG. 7 is a diagram illustrating a spectroscope according to one or more embodiments.

Referring to FIG. 7, the spectroscope 9 may include a plane driver 92. The plane driver 92 may be connected to the plane detector 97. The plane driver 92 may drive the plane detector 97 to move. The plane driver 92 may adjust a first distance DS1 between the spectral dispersion device 95 and the plane detector 97. The plane driver 92 may adjust a second distance DS2 between the plane detector 97 and the third lens 91c.

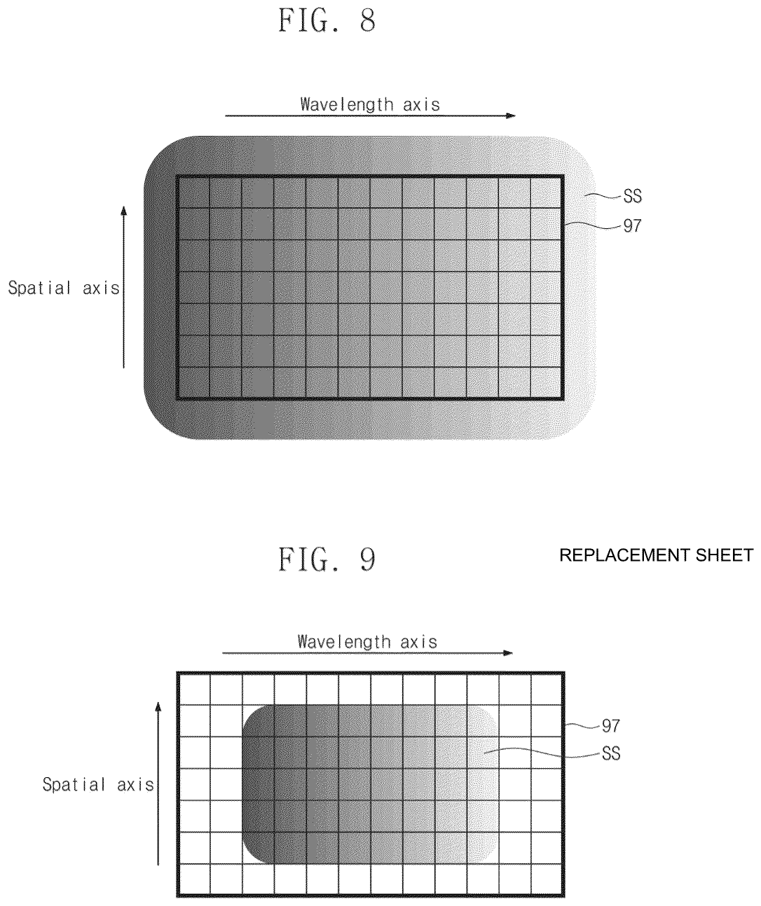

FIG. 8 is a plan view illustrating a plane detector according to one or more embodiments. FIG. 9 is a plan view illustrating a plane detector according to one or more embodiments.

Referring to FIGS. 8 and 9, it may be seen that the spectrum zone SS is changed due to movement of the plane detector 97. In FIG. 8, the spectrum zone SS on the plane detector 97 may be detected when the plane detector 97 is positioned far away from the third lens 91c or the spectral dispersion device 95. In FIG. 9, the spectrum zone SS on the plane detector 97 may be detected when the plane detector 97 is positioned near the third lens 91c or the spectral dispersion device 95. An increase in the second distance DS2 may cause an increase in the first distance DS1. A reduction in the second distance DS2 may cause a reduction in the first distance DS1. A description of the first distance DS1 may be applicable to the second distance DS2.

Referring to FIG. 8, when the first distance DS1 is increased, the spectrum zone SS may have a size greater than that of the plane detector 97. An increase in the first distance DS1 may cause a reduction in spatial range detectable by the plane detector 97. An increase in the first distance DS1 may cause a reduction in resolution to spectrum.

Referring to FIG. 9, when the first distance DS1 is reduced, the spectrum zone SS may have a size less than that of the plane detector 97. A reduction in the first distance DS1 may cause an increase in spatial range of the spectrum zone SS detectable by the plane detector 97. A reduction in the first distance DS1 may cause an increase in resolution to spectrum. Therefore, the first distance DS1 or the second distance DS2 may be adjusted to control resolution or range of the slit region P that is to be analyzed.

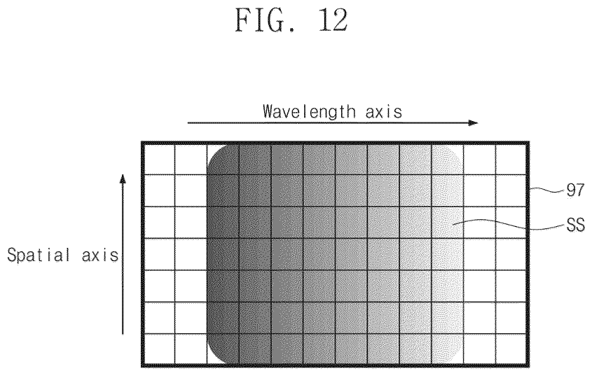

FIG. 10 is a diagram illustrating a spectroscope according to one or more embodiments. FIG. 11 is a plan view illustrating a plane detector according to one or more embodiments. FIG. 12 is a plan view illustrating a plane detector according to one or more embodiments.

Referring to FIG. 10, the spectroscope 9 may include a slit controller 931. The slit controller 931 may adjust a width of the slit 93h. The slit controller 931 may control the width of the slit 93h to adjust resolution of the light L.

FIG. 11 depicts the spectrum zone SS and the plane detector 97 when the width of the slit 93h is reduced. A reduction in width of the slit 93h may allow the spectrum zone SS to have a width greater than that of the plane detector 97. A reduction in width of the slit 93h may cause a reduction in wavelength range detectable by the plane detector 97. A reduction in width of the slit 93h may cause a reduction in resolution.

FIG. 12 depicts the spectrum zone SS and the plane detector 97 when the width of the slit 93h is increased. An increase in width of the slit 93h may allow the spectrum zone SS to have a width less than a horizontal side of the plane detector 97. An increase in width of the slit 93h may cause an increase in wavelength range detectable by the plane detector 97. An increase in width of the slit 93h may cause an increase in resolution. Therefore, the width of the slit 93h may be adjusted to control a wavelength range or resolution that is to be analyzed.

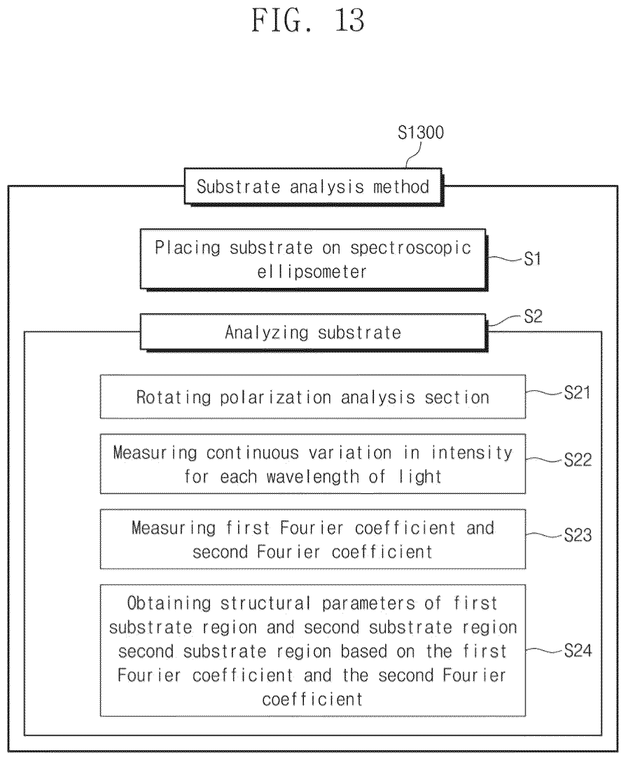

FIG. 13 is a flowchart illustrating a substrate analysis method according to one or more embodiments.

Referring to FIG. 13, a substrate analysis method S1300 may include placing the substrate W on the spectroscopic ellipsometer SE in operation S1 and analyzing the substrate W in operation S2. The substrate analysis operation S2 may include rotating the polarization analysis assembly 7 in operation S21, measuring a continuous variation in intensity for each wavelength of the light L in operation S22, measuring a first Fourier coefficient and a second Fourier coefficient in operation S23, and obtaining structural parameters of a first substrate region and a second substrate region based on the first Fourier coefficient and the second Fourier coefficient in operation S24.

The spectroscopic ellipsometer SE may be configured to obtain the structural parameters of the first substrate region and the second substrate region based on the first Fourier coefficient and the second Fourier coefficient. However, embodiments are not limited to the obtainment of the structural parameter of the substrate W. A length of the slit 93h may cause an increase in an analyzing region of the substrate W. The slit 93h may be used to simultaneously analyze a linear region of the substrate W.

According to a spectroscopic ellipsometer and a substrate analysis method using the same in accordance with one or more embodiments, a structure of a specific line region of a substrate may be recognized at once. As a line slit assembly provides a slit that linearly extends, a straight region of the substrate may be simultaneously analyzed. When a two-dimensional area of the substrate is analyzed, a substrate support or a spectroscope may move vertically to the observed straight region. Structural parameters of the straight region of the substrate may be simultaneously measured to save time required for understanding properties of the substrate. As a structure of the straight region of the substrate is recognized concurrently, failure of semiconductor chips on the substrate may be promptly ascertained.

According to a spectroscopic ellipsometer and a substrate analysis method using the same in accordance with one or more embodiments, a polarization analysis assembly may rotate to increase a space and wavelength resolution. Compared with when data of light intensity for continuous wavelength, sensitivity may be reduced when a polarization filter is used fixed at a specific angle without rotating the polarization analysis assembly. As the polarization analysis assembly is rotated, a substrate structural parameter similar to an actual structural parameter may be obtained.

According to a spectroscopic ellipsometer and a substrate analysis method using the same in accordance with one or more embodiments, resolution, a spatial range, and a wavelength range of a region to be observed may be controlled. For example, a first distance or a second distance may be controlled to change a wavelength range of a substrate region to be observed. A slit width may be changed to control the wavelength range of the substrate region to be observed. A spatial range of the substrate region to be observed may be adjusted by controlling the first distance, the second distance is controlled, or the slit width. The control of the first distance or the slit width may cause a variation in resolution.

According to a spectroscopic ellipsometer and a substrate analysis method using the same in one or more embodiments, a spectroscope may include therein a line slit assembly that provides a straight line-shaped slit.

According to a spectroscopic ellipsometer and a substrate analysis method using the same in one or more embodiments, spectral data of a substrate line region may be obtained.

According to a spectroscopic ellipsometer and a substrate analysis method using the same in one or more embodiments, a Fourier coefficient and a structural parameter of a substrate line region may be determined.

According to a spectroscopic ellipsometer and a substrate analysis method using the same in one or more embodiments, a rotary spectroscope may be caused to obtain a continuous polarization signal of a substrate line region.

According to a spectroscopic ellipsometer and a substrate analysis method using the same in one or more embodiments, it may be easy to perform a large-area analysis of a substrate.

At least one of the devices, units, components, modules, units, or the like represented by a block or an equivalent indication in the above embodiments including, but not limited to, FIGS. 1-3, 7 and 10 may be physically implemented by analog and/or digital circuits including one or more of a logic gate, an integrated circuit, a microprocessor, a microcontroller, a memory circuit, a passive electronic component, an active electronic component, an optical component, and the like, and may also be implemented by or driven by software and/or firmware (configured to perform the functions or operations described herein).

Each of the embodiments provided in the above description is not excluded from being associated with one or more features of another example or another embodiment also provided herein or not provided herein but consistent with the disclosure.

While the disclosure has been particularly shown and described with reference to embodiments thereof, it will be understood that various changes in form and details may be made therein without departing from the spirit and scope of the following claims.

What is claimed is:

1. A spectroscopic ellipsometer, comprising:
a light source configured to emit light;
a polarizer configured to polarize the light emitted from the light source;
a substrate support supporting a substrate;
a polarization analysis assembly that is rotatable and optically connected to the substrate support; and
a spectroscope configured to disperse the light from the polarization analysis assembly,
wherein the spectroscope comprises:
a lens configured to change a propagation path of the light from the polarization analysis assembly;
a line slit assembly comprising a slit extending linearly and configured to extract a portion of the light from the lens;
a spectral dispersion device configured to disperse the light from the line slit assembly; and
a plane detector optically connected to the spectral dispersion device and configured to continuously detect the dispersed light that is dispersed by the spectral dispersion device.

2. The spectroscopic ellipsometer of claim 1, wherein the spectral dispersion device comprises a prism or a diffraction grating.

3. The spectroscopic ellipsometer of claim 1, further comprising a first compensator between the polarizer and the substrate support,
wherein the first compensator configured to delay a phase of the light from the polarizer.

4. The spectroscopic ellipsometer of claim 1, wherein the polarization analysis assembly comprises:
an analyzer configured to determine information about polarization of the light from the substrate support; and
a second compensator between the substrate support and the analyzer, the second compensator configured to change a phase of the light from the substrate support.

5. The spectroscopic ellipsometer of claim 4, wherein the polarization analysis assembly further comprises a polarization rotator configured to rotate at least one of the analyzer and the second compensator.

6. The spectroscopic ellipsometer of claim 1, wherein the line slit assembly comprises a slit controller configured to adjust a width of the slit.

7. The spectroscopic ellipsometer of claim 1, further comprising a plane driver configured to adjust a distance between the spectral dispersion device and the plane detector.

8. The spectroscopic ellipsometer of claim 1, wherein the lens comprises a first collimating lens and a second collimating lens configured to control a propagation direction of the light from the polarization analysis assembly, and
wherein the line slit assembly is between the first collimating lens and the second collimating lens.

9. The spectroscopic ellipsometer of claim 8, wherein the spectroscope further comprises a plane driver configured to adjust a distance between the spectral dispersion device and the plane detector,
wherein the lens further comprises a third lens between the plane detector and the spectral dispersion device, and
wherein the plane driver is further configured to adjust a distance between the third lens and the plane detector.

10. A spectroscopic ellipsometer, comprising:
a light source configured to emit light;
a polarizer configured to polarize the light emitted from the light source;
a substrate support configured to support a substrate;
a rotatable analyzer configured to determine a degree of polarization of the light from the polarizer and a position of a polarization plane; and
a spectroscope configured to disperse the light from the rotatable analyzer,
wherein the spectroscope comprises:
a first collimating lens configured to concentrate the light from the rotatable analyzer to form an image;
a second collimating lens that is spaced apart from the first collimating lens and configured to parallel propagate the light from the first collimating lens;
a line slit assembly between the first collimating lens and the second collimating lens and comprising a slit extending linearly;
a spectral dispersion device optically connected to the second collimating lens and configured to disperse the light from the second collimating lens; and
a plane detector optically connected to the spectral dispersion device and configured to continuously detect the dispersed light from the spectral dispersion device.

11. The spectroscopic ellipsometer of claim 10, wherein the line slit assembly comprises a slit controller configured to control a resolution of the light from the first collimating lens by adjusting a width of the slit.

12. The spectroscopic ellipsometer of claim 10, wherein the spectroscope further comprises a plane driver configured to adjust a distance between the plane detector and the spectral dispersion device.

13. The spectroscopic ellipsometer of claim 12, wherein the spectroscope further comprises a third lens between the spectral dispersion device and the plane detector, the third lens configured to pass the light from the spectral dispersion device to toward the plane detector, and
wherein the plane driver is further configured to adjust a distance between the third lens and the plane detector.

14. The spectroscopic ellipsometer of claim 10, further comprising a first compensator between the polarizer and the substrate support, the first compensator configured to convert a linear polarization into a circular polarization or an elliptical polarization.

15. The spectroscopic ellipsometer of claim 14, further comprising a second compensator between the substrate support and the rotatable analyzer,
wherein the second compensator is configured to change a phase of the light from the polarizer.

16. The spectroscopic ellipsometer of claim 15, further comprising:
a polarization rotator configured to rotate the second compensator; and
a central processing unit connected to the plane detector,
wherein the central processing unit is configured to determine a structural parameter of the substrate based on data obtained from the plane detector.

17. A substrate analysis method, comprising:
providing a substrate on a spectroscopic ellipsometer; and
analyzing the substrate,
wherein the spectroscopic ellipsometer comprises:
a light source configured to emit light;
a polarizer configured to polarize the light emitted from the light source;
a substrate support configured to support the substrate;
a rotatable polarization analysis assembly configured to determine information about polarization of the light from the substrate support; and
a spectroscope configured to disperse the light from the rotatable polarization analysis assembly,
wherein the spectroscope comprises:
a line slit assembly comprising a slit extending linearly;
a spectral dispersion device configured to disperse the light from the line slit assembly; and
a plane detector optically connected to the spectral dispersion device,
wherein the rotatable polarization analysis assembly comprises an analyzer configured to determine the information about the polarization of the light from the substrate support,
wherein the slit comprises a first slit region and a second slit region,
wherein the substrate comprises:
a first substrate region corresponding to the first slit region; and
a second substrate region corresponding to the second slit region, and
wherein the analyzing the substrate comprises:
rotating the rotatable polarization analysis assembly;
measuring a continuous variation in intensity in accordance with a wavelength of the light caused by rotation of the rotatable polarization analysis assembly;
measuring a first Fourier coefficient of the first slit region and a second Fourier coefficient of the second slit region; and
obtaining structural parameters of the first substrate region and the second substrate region based on the first Fourier coefficient and the first Fourier coefficient.

18. The substrate analysis method of claim 17, wherein the rotatable polarization analysis assembly comprises a compensator configured to change a phase of the light from the substrate support, and
wherein the rotating the rotatable polarization analysis assembly comprises rotating at least one of the compensator and the analyzer.

19. The substrate analysis method of claim 17, wherein the spectroscopic ellipsometer further comprises a plane driver configured to drive the plane detector to move, and
wherein the analyzing the substrate comprises adjusting, by the plane driver, a distance between the plane detector and the substrate support.

20. The substrate analysis method of claim 17, wherein the line slit assembly comprises a slit controller configured to adjust a width of the slit, and
wherein the analyzing the substrate comprises adjusting, by the slit controller, the width of the slit.
